(19) United States
(12) Patent Application Publication
(10) Pub. No.: US 2006/0180899 A1
(43) Pub. Date: Aug. 17, 2006

(54) Semiconductive chip device having insulating coating layer and method of manfacturing the same

(75) Inventors: Kyung Hee Ko, Suwon (KR); Ji Hwan Shin, Yongin (KR); Chang Hak Choi, Suwon (KR)

Correspondence Address: McDermott Will & Emery LLP, 600 13th Street, N.W., Washington, DC, 20005-3096, US

(73) Assignee: SAMSUNG ELECTRO-MECHANICS CO., LTD.

(21) Appl. No.: 11/126,169

(22) Filed: May 11, 2005

(30) Foreign Application Priority Data
Feb. 14, 2005 (KR) 10-2005-12050

(51) Int. Cl. H01L 23/58

(52) U.S. Cl. 257/634

(57) ABSTRACT

Disclosed herein is a semiconductive chip device having an insulating coating layer, which includes a multi-crystalline semiconductive chip requiring surface insulation properties, outer electrodes formed at both ends of the semiconductive chip, and an insulating coating layer formed by fusing glass powder to a silane coupling agent on the surface of the semiconductive chip. In addition, a method of manufacturing the semiconductive chip device having an insulating coating layer is provided, which comprises: preparing a multi-crystalline semiconductive chip requiring surface insulation properties, and etching the multi-crystalline semiconductive chip; dipping the etched semiconductive chip into a silane coupling solution, and removing the aqueous component from the solution attached to the surface of the semiconductive chip; attaching glass powder to the surface of the semiconductive chip having no aqueous component, and primarily heat treating the semiconductive chip; and forming outer electrodes on the primarily heat treated semiconductive chip, and, secondarily heat treating the semiconductive chip, thereby forming the insulating coating layer on the surface of the semiconductive chip.

### RELATED APPLICATIONS

The present application is based on, and claims priority from, Korean Application Number 2005-12050, filed Feb. 14, 2005, the disclosure of which is incorporated by reference herein in its entirety.

### BACKGROUND OF THE INVENTION

1. Field of the Invention

The present invention relates, generally, to a semiconductive chip device having an insulating coating layer thereon, and a method of manufacturing the same. More specifically, the present invention relates to a semiconductive chip device on which an insulating coating layer, acting to effectively prevent flux invasion when performing a subsequent reflow soldering process so as to maintain initial insulation resistance, is formed, and a method of manufacturing such a semiconductive chip device.

2. Description of the Related Art

Recently, while various electronic devices, such as mobile communication terminals, have been fabricated to be miniaturized, circuit components used therefor are required to be miniaturized and highly integrated. Thus, the circuit components have been designed to have low rated voltage and rated current.

Typically represented by the above component, a varistor is a device significantly manifesting nonlinear voltage-current characteristics due to the resistance varying with the applied voltage. The varistor, which is operated as an insulative circuit device under normal conditions, has a drastically decreased resistance value when the applied voltage is higher than a specified value. Thus, the varistor having the above characteristics is widely employed to protect semiconductive devices from surge voltage.

Of varistors, a zinc oxide varistor is mainly used, which has excellent nonlinear voltage-current characteristics and high surge absorption power. Such a varistor is manufactured by mixing zinc oxide as a main ingredient of the varistor with a plurality of additives, to prepare ceramic powder for a varistor, which is then molded and sintered. In the varistor, an energy barrier, corresponding to a boundary barrier layer, is formed at the zinc oxide grain boundaries, due to an impurity energy level, therefore manifesting excellent nonlinear voltage-current characteristics.

FIG. 1a is a sectional view showing a conventional semiconductive chip device having no insulating coating layer, suitable for use in a chip varistor. As shown in FIG. 1a, the chip varistor is composed of a ceramic laminate including a plurality of ceramic layers 1 formed of a zinc oxide-based ceramic material and inner electrodes 3 interposed between the ceramic layers 1 to be alternately connected to both ends of the ceramic layers 1, and outer electrodes 5 formed at both ends of the ceramic laminate, each of which is electrically connected to at least one of the inner electrodes.

However, when the chip varistor is mounted on a printed circuit board (PCB) using a reflow soldering process, the lower surface of the varistor is corroded by the flux. A solder paste, which is used for reflow soldering of chip components to be mounted on the PCB, includes a Cl⁻ ion-containing flux to increase the solderability. The liquid flux moves between the PCB and the varistor, and thus, corrodes the surface of the chip varistor, in particular, the grain boundary. Hence, the flux composition attacks the surface of the varistor upon soldering, and melts ZnO and Sb₂O₃ having low acid resistance among the materials constituting the varistor. Thereby, Zn and Sb ions are excessively included in the flux, and the initial resistance value of the chip varistor is drastically decreased after the soldering.

In the general fabrication of the chip varistor, after the outer electrodes are formed to be electrically connected to the inner electrodes, the surfaces of the outer electrodes are plated with Cu, Ni or Sn. However, the chip varistor functions as a nonconductor under normal conditions due to the semiconductivity of ZnO ceramics, and then is changed to be conductive at a critical voltage or more. Thus, when the chip varistor is electroplated, the surface of the ceramic body is plated. Thereby, the ceramic body is changed into a conductor, resulting in mutually bridged outer electrodes at both ends thereof.

Accordingly, techniques for solving the conventional problems have been proposed. In this regard, Korean Patent Laid-open Publication No. 2002-45782 discloses a method of manufacturing a glass film using a wet process, which includes dipping an etched chip varistor into a slurry of glass powder, rotatably drying the chip to coat the chip with the glass slurry, heat treating the chip coated with the glass slurry such that the glass melts and enters pores of the surface of the chip due to a capillary phenomenon, to form a uniform glass coating layer on the chip. However, the above technique is disadvantageous because the edge portions of the chip are not sufficiently coated, and the coating layer has an undesired thickness.

In addition, Korean Patent Laid-open Publication No. 2003-68863 discloses a chip varistor and a method of manufacturing the chip varistor, including coating the varistor with negative type PR, coating outer electrodes of the varistor with positive type PR, curing the negative type PR, and removing the coated PR layer. However, the above technique has complicated processes, thus negating economic benefits, and is unsuitable for actual applications.

### SUMMARY OF THE INVENTION

Therefore, the present invention has been made keeping in mind the above problems occurring in the related art, and an object of the present invention is to provide a semiconductive chip device, which is advantageous because its manufacturing process is simplified, the amount of glass to be attached thereto is effectively increased, and a highly resistant insulating coating layer having excellent reproducibility is formed thereon.

Another object of the present invention is to provide a method of manufacturing a semiconductive chip device having an insulating coating layer.

In order to accomplish the above objects, the present invention provides a semiconductive chip device, comprising a multi-crystalline semiconductive chip requiring surface insulation properties; outer electrodes formed at both ends of the semiconductive chip; and an insulating coating layer formed by fusing glass powder to a silane coupling agent on the surface of the semiconductive chip.

In addition, the present invention provides a semiconductive chip device, comprising a semiconductive ceramic laminate, which includes a plurality of dielectric layers and a plurality of inner electrodes alternately interposed between the dielectric layers; outer electrodes formed at both ends of the ceramic laminate, each of which is electrically connected to at least one of the inner electrodes; and an insulating coating layer formed by fusing glass powder to a silane coupling agent on the surface of the ceramic laminate.

Further, the present invention provides a method of manufacturing a semiconductive chip device having an insulating coating layer, comprising: preparing a multi-crystalline semiconductive chip requiring surface insulation properties, and etching the multi-crystalline semiconductive chip; dipping the etched semiconductive chip into a silane coupling solution, and removing the aqueous component from the solution attached to the surface of the semiconductive chip; attaching glass powder to the surface of the semiconductive chip having, and primarily heat treating the semiconductive chip; and forming outer electrodes on the primarily heat treated semiconductive chip, and secondarily heat treating the semiconductive chip, thereby forming an insulating coating layer on the surface of the semiconductive chip.

Furthermore, the present invention provides a method of manufacturing a semiconductive chip device having an insulating coating layer, comprising: preparing a semiconductive ceramic laminate, which includes dielectric layers and inner electrodes alternately interposed between the dielectric layers, and etching the semiconductive ceramic laminate; dipping the etched ceramic laminate into a silane coupling solution, and drying the ceramic laminate; attaching glass powder onto the surface of the dried ceramic laminate, and primarily heat treating the ceramic laminate; and forming outer electrodes on the primarily heat treated ceramic laminate, secondarily heat treating the ceramic laminate, and plating the outer electrodes.

Also, the present invention provides a semiconductive chip device, manufactured according to the above manufacturing methods.

### BRIEF DESCRIPTION OF THE DRAWINGS

The above and other objects, features and advantages of the present invention will be more clearly understood from the following detailed description taken in conjunction with the accompanying drawings, in which:

FIG. 1a is a sectional view showing a conventional semiconductive chip device having no insulating coating layer, for use in a chip varistor;

FIG. 1b is a sectional view showing a semiconductive chip device having an insulating coating layer, for use in a chip varistor, according to the present invention;

FIG. 2 is a view showing a process of manufacturing the semiconductive chip device, according to the present invention; and

FIGS. 3a to 3c are views showing a process of forming the insulating coating layer, according to the present invention.

### DESCRIPTION OF THE PREFERRED EMBODIMENTS

Hereinafter, a detailed description will be given of the present invention, with reference to the appended drawings.

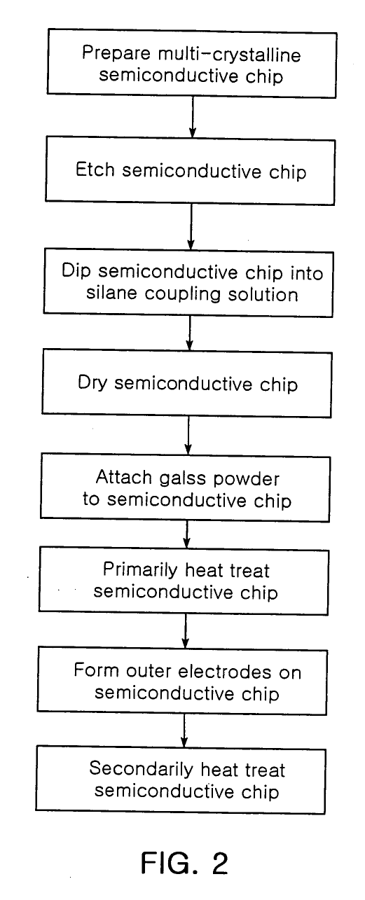

FIG. 2 is a view showing a process of manufacturing a semiconductive chip device, according to the present invention. As shown in FIG. 2, a multi-crystalline semiconductive chip requiring surface insulation properties is first prepared. The multi-crystalline semiconductive chip requiring surface insulation properties is applied to chip varistors, PTCRs, MTCRs, etc., but is not limited thereto.

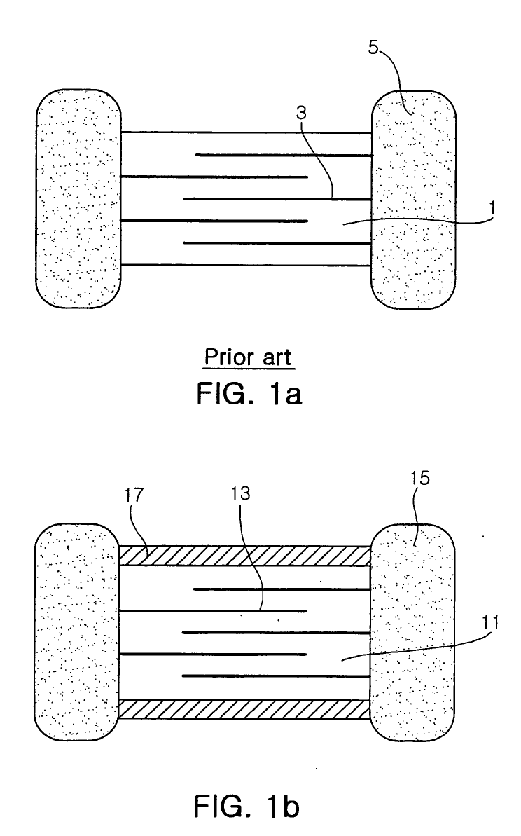

Multi-crystalline semiconductive chips are largely classified into a laminate type and a disc type, each of which may be used in the present invention. Referring to FIG. 1b, the laminate type semiconductive chip is formed into a semiconductive ceramic laminate, including dielectric layers 11 and inner electrodes 13 interposed between the dielectric layers 11 to be alternately connected to both ends of the dielectric layers 11. As this time, the dielectric layer 11 may be formed using a tape casting process or a spin coating process.

In the case of a chip varistor, the dielectric layer is composed of any one selected from among ZnO, BiO₂, MnO₂, Sb₂O₅, Co₂O₃, and mixtures thereof. The inner electrode can be formed of Ag—Pd using a screen printing process. The laminate thus obtained is cut, sintered at 900-1200° C., and then polished for 12-75 hr, to fabricate the semicondcutive chip that is the semiconductive ceramic laminate. However, the above process conditions are merely used to be illustrative in the present invention, and the present invention is not limited thereto.

Then, the above semiconductive chip is etched. As such, the etching process is used to increase the efficiency of the subsequent glass powder attachment, thus increasing the adhesive strength between the semiconductive chip and the glass film.

The semiconductive chip is preferably etched using a 0.1-10% HCl solution. More preferably, the etching process is conducted in the time range of from 1 sec to 30 min.

To remove hydrochloric acid attached to the surface of the semiconductive chip or any material attached after the etching, a water washing process may be carried out for 3-30 min.

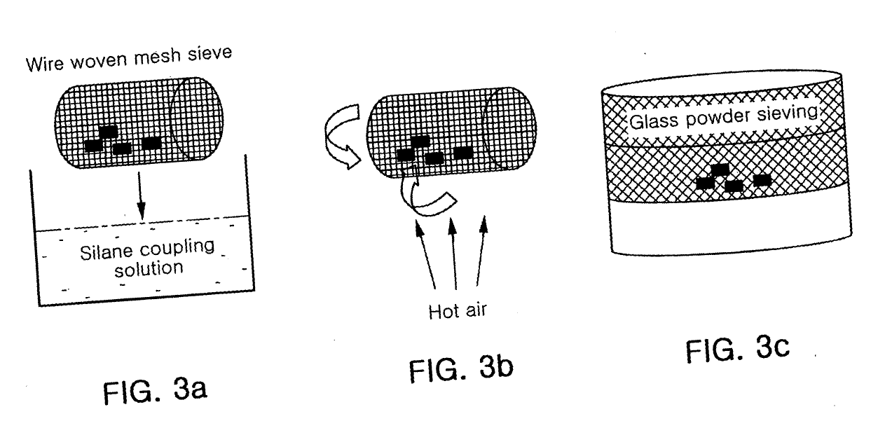

The semiconductive chip, which is the etched ceramic laminate, is dipped into a silane coupling solution so that the surface of the semiconductive chip is modified to be adhesive to increase the efficiency of the subsequent glass attachment. Therefore, as shown in FIG. 3a, a series of processes of loading a plurality of semiconductive chips into a wire woven mesh sieve and then dipping the semiconductive chips loaded into the mesh sieve into a silane coupling solution is used, as shown in FIG. 3a.

The silane coupling solution can be obtained by mixing pure water with a silane coupling agent. At this time, the concentration of the silane coupling agent in the solution is preferably limited to 0.5-20%. If the concentration exceeds 20%, attachment to the chip may be weakened.

In the present invention, limitations are not imposed on the specific kinds and compositions of the silane coupling agent used to prepare the silane coupling solution. For example, the silane coupling agent can comprise any one selected from among 2-(3,4-epoxycyclohexyl) ethyltrimethoxysilane, 3-glycidoxypropyl trimethoxysilane, 3-glycidoxypropyl methyldiethoxy silane, and 3-glycidoxypropyl triethoxysilane.

Further, the dipping time is preferably limited to the range of from 30 sec to 30 min in the present invention.

Thereafter, as in FIG. 3b, the dipped semiconductive chip is dried using hot air to remove the aqueous component from the solution attached thereto. The removal of the aqueous component is required so that the subsequent glass attachment can be uniform.

As such, the drying conditions are not particularly limited in the present invention. Any drying method may be used so long as it acts to remove the aqueous component sufficiently from the solution attached to the surface of the chip.

Preferably, the drying temperature is limited to the range of from room temperature to 150° C.

Subsequently, the glass powder is attached to the surface of the dried semiconductive chip. As shown in FIG. 3c, the attachment of the glass powder is carried out by loading the semiconductive chip into a vessel containing glass powder having a uniform particle size through sieving, and then agitating the vessel, but it is not limited thereto.

The glass powder can comprise any one selected from among Bi₂O₃, B₂O₃, Al₂O₃, P₂O₅, SnO₂, SiO₂, ZnO, Li₂O₃, K₂O, and mixtures thereof. In addition, glass powder having a softening point of 500 to 700° C. can be preferably used.

More preferably, P₂O₅—ZnO—Al₂O₃ based powder, which comprises 30-60 wt % P₂O₅, 30-60 wt % ZnO and 10 wt % or less Al₂O₃, or SiO₂—Bi₂O₃—B₂O₃—ZnO based powder, which comprises 10 wt % or less SiO₂, 20-90 wt % Bi₂O₃, 10-40 wt % B₂O₃ and 10 wt % or less ZnO, can be selectively used.

The semiconductive chip having the surface which glass powder is attached thereto is primarily heat treated. The heat treatment functions to melt the powder attached to the surface of the chip, thus increasing the adhesive strength between the chip and the glass coating layer. In addition, the heat treatment allows the subsequent application process for the formation of the outer electrodes to be easily performed.

In such a case, the primary heat treatment temperature is preferably limited to 600-800° C. This is because the adhesive strength between the glass coating layer and the chip is efficiently increased in the above temperature range.

As is apparent from FIG. 1b, outer electrodes 15 are formed at both ends of the primarily heat treated semiconductive chip, and then the semiconductive chip having outer electrodes 15 is secondarily heat treated. The outer electrodes 15 can be formed by applying the Ag paste on both end surfaces of the chip for electrical connection with the inner electrodes 13 of the semiconductive chip.

After the paste is applied to form the outer electrodes 15, the secondary heat treatment is conducted to sinter the electrodes. The secondary heat treatment functions to sinter the applied outer electrodes 15 to be respectively electrically connected to at least one of the inner electrodes 13. Through the heat treatment, glass insulating coating layers 17 are formed on the upper and lower surfaces of the semiconductive chip, as in FIG. 1b. That is, the glass powder attached to the surface of the semiconductive chip is completely and uniformly fused to the silane coupling agent, yielding a desired glass coating layer 17.

Considering the above conditions, the secondary heat treatment temperature is preferably limited to 600-800° C.

And in the present invention, the outer electrodes 15 can be preferably plated with Ni or Sn for soldering that is required in order to be mounted on a substrate, such as PCB.

The semiconductive chip device thus fabricated can comprise the multi-crystalline semiconductive chip requiring surface insulation properties, the outer electrodes formed at both ends of the semiconductive chip, and the insulating coating layer formed by fusing glass powder to the silane coupling agent on the surface of the semiconductive chip.

In addition, the semiconductive chip can be formed into a semiconductive ceramic laminate including a plurality of dielectric layers and a plurality of inner electrodes interposed between the dielectric layers to be alternately connected to both ends of the dielectric layers. And the ceramic laminate further can include outer electrodes, each of which is electrically connected to at least one of the inner electrodes.

A better understanding of the present invention may be obtained in light of the following example which is set forth to illustrate, but is not to be construed to limit the present invention.

### EXAMPLE

A semiconductive ceramic laminate, including a plurality of dielectric layers formed of ZnO and Bi₂O₃ and a plurality of inner electrodes interposed between the dielectric layers to be alternately connected to both ends of the dielectric layers, was fabricated and then cut, to manufacture a chip sample. The sample was sintered and polished under general conditions, to manufacture a plurality of multi-crystalline semiconductive chips for chip varistors. The semiconductive chips were dipped into a 2% aqueous HCl solution, etched and washed with water. Subsequently, the semiconductive chips were loaded into a wire woven mesh sieve, which was then dipped into a silane coupling solution containing 5% 3-glycidoxypropyl trimethoxysilane, and dried using a hot air dryer for 20 min.

The dried semiconductive chips were coated with glass powders having different compositions (wt %) as shown in Tables 1 and 2, below, and then heat treated at 600° C.

TABLE 1

| | P₂O₅ | Al₂O₃ | ZnO | Li₂O₃ | K₂O | Na₂O |
|---|---|---|---|---|---|---|
| | (wt %) | (wt %) | (wt %) | (wt %) | (wt %) | (wt %) |
| Composition | 30 or | 10 or | 30 or | 10 or | 10 or | 10 or |
| Ex. 1 | more | less | more | less | less | less |
| Composition | 40 or | 10 or | 40 or | — | — | 10 or |
| Ex. 2 | more | less | more | | | less |

TABLE 2

| | Bi₂O₃ | B₂O₃ | ZnO | SiO₂ | Li₂O₃ | Na₂O | Al₂O₃ |
|---|---|---|---|---|---|---|---|
| | (wt %) | (wt %) | (wt %) | (wt %) | (wt %) | (wt %) | (wt %) |
| Composition | 80 or | 10 or | 10 or | 10 or | 10 or | 10 or | 10 or |
| Ex. 3 | more | more | less | less | less | less | less |
| Composition | 30 or | 40 or | 10 or | 10 or | 10 or | 10 or | 10 or |
| Ex. 4 | more | less | less | less | less | less | less |

The Ag paste was applied on both end surfaces of the heat treated semiconductive chips to form outer electrodes, and then secondary heat treatment was performed at 700° C. The outer electrodes of the heat treated semiconductive chips were plated with Ni. As such, as the results of observing the plating bleed-out with the naked eye, it can be confirmed that all of the semiconductive chips used in Example have no plating bleed-out or reflow defects thereon. This is because the insulating coating layer formed by fusing glass powder to the silane coupling agent is uniformly and densely formed on the surface of the semiconductive chip.

As described hereinbefore, the present invention provides a semiconductive chip device having an insulating coating layer and a method of manufacturing the same. The method of the present invention is advantageous because its process is simplified, compared to conventional wet methods using slurry. Further, the loss of glass powder used in the present invention is decreased, and as well, a semiconductive chip device having a uniform and complete insulating coating layer is readily manufactured.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductive chip device, comprising:
a multi-crystalline semiconductive chip requiring surface insulation properties;
outer electrodes formed at both ends of the semiconductive chip; and
an insulating coating layer formed by fusing glass powder to a silane coupling agent on the surface of the semiconductive chip.

2. The semiconductive chip device as set forth in claim 1, wherein the glass powder is selected from among Bi₂O₃, B₂O₃, Al₂O₃, P₂O₅, SnO₂, SiO₂, ZnO, Li₂O₃, K₂O, and mixtures thereof.

3. The semiconductive chip device as set forth in claim 1 or 2, wherein the glass powder has a softening point ranging from 500 to 700° C.

4. The semiconductive chip device as set forth in claim 1 or 2, wherein the glass powder is P₂O₅—ZnO—Al₂O₃ based powder comprising 30-60 wt % P₂O₅, 30-60 wt % ZnO and 10 wt % or less Al₂O₃.

5. The semiconductive chip device as set forth in claim 1 or 2, wherein the glass powder is SiO₂—Bi₂O₃—B₂O₃—ZnO based powder comprising 10 wt % or less SiO₂, 20-90 wt % Bi₂O₃, 10-40 wt % B₂O₃ and 10 wt % or less ZnO.

6. The semiconductive chip device as set forth in claim 1, wherein the silane coupling agent comprises any one selected from among 2-(3,4-epoxycyclohexyl) ethyltrimethoxysilane, 3-glycidoxypropyl trimethoxysilane, 3-glycidoxypropyl methyldiethoxysilane, and 3-glycidoxypropyl triethoxysilane.

7. A semiconductive chip device, comprising:
a semiconductive ceramic laminate, which includes a plurality of dielectric layers and a plurality of inner electrodes alternately interposed between the dielectric layers;
outer electrodes formed at both ends of the ceramic laminate, each of which is electrically connected to at least one of the inner electrodes; and
an insulating coating layer formed by fusing glass powder to a silane coupling agent on the surface of the ceramic laminate.

8. The semiconductive chip device as set forth in claim 7, wherein the glass powder is selected from among Bi₂O₃, B₂O₃, Al₂O₃, P₂O₅, SnO₂, SiO₂, ZnO, Li₂O₃, K₂O, and mixtures thereof.

9. The semiconductive chip device as set forth in claim 7 or 8, wherein the glass powder has a softening point ranging from 500 to 700° C.

10. The semiconductive chip device as set forth in claim 7 or 8, wherein the glass powder is P₂O₅—ZnO—Al₂O₃ based powder comprising 30-60 wt % P₂O₅, 30-60 wt % ZnO and 10 wt % or less Al₂O₃.

11. The semiconductive chip device as set forth in claim 7 or 8, wherein the glass powder is SiO₂—Bi₂O₃—B₂O₃—ZnO based powder comprising 10 wt % or less SiO₂, 20-90 wt % Bi₂O₃, 10-40 wt % B₂O₃ and 10 wt % or less ZnO.

12. The semiconductive chip device as set forth in claim 7, wherein the silane coupling agent comprises any one selected from among 2-(3,4-epoxycyclohexyl) ethyltrimethoxysilane, 3-glycidoxypropyl trimethoxysilane, 3-glycidoxypropyl methyldiethoxy silane, and 3-glycidoxypropyl triethoxysilane.

13. The semiconductive chip device as set forth in claim 7, wherein the dielectric layer includes any one selected from among ZnO, BiO₂, MnO₂, Sb₂O₅, Co₂O₃, and mixtures thereof.

14. The semiconductive chip device as set forth in claim 7, wherein the semiconductive chip device is a chip varistor.

15. A method of manufacturing a semiconductive chip device having an insulating coating layer, comprising:
preparing a multi-crystalline semiconductive chip requiring surface insulation properties, and etching the multi-crystalline semiconductive chip;
dipping the etched semiconductive chip into a silane coupling solution, and removing an aqueous component from the solution attached to the surface of the semiconductive chip;
attaching glass powder to the surface of the semiconductive chip, and primarily heat treating the semiconductive chip; and
forming outer electrodes on the primarily heat treated semiconductive chip, and secondarily heat treating the semiconductive chip, thereby forming an insulating coating layer on the surface of the semiconductive chip.

16. The method as set forth in claim 15, wherein the etching of the semiconductive chip is performed using a 0.1-10% HCl solution.

17. The method as set forth in claim 15, wherein the silane coupling solution includes a 0.5-20% silane coupling agent.

18. The method as set forth in claim 17, wherein the silane coupling agent comprises any one selected from among 2-(3,4-epoxycyclohexyl)ethyltrimethoxysilane, 3-glycidoxypropyl trimethoxysilane, 3-glycidoxypropyl methyldiethoxysilane, and 3-glycidoxypropyl triethoxysilane.

19. The method as set forth in claim 15, wherein the glass powder is selected from among Bi₂O₃, B₂O₃, Al₂O₃, P₂O₅, SnO₂, SiO₂, ZnO, Li₂O₃, K₂O, and mixtures thereof.

20. The method as set forth in claim 15 or 19, wherein the glass powder is P₂O₅—ZnO—Al₂O₃ based powder comprising 30-60 wt % P₂O₅, 30-60 wt % ZnO and 10 wt % or less Al₂O₃.

21. The method as set forth in claim 15 or 19, wherein the glass powder is SiO₂—Bi₂O₃—B₂O₃—ZnO based powder comprising 10 wt % or less SiO₂, 20-90 wt % Bi₂O₃, 10-40 wt % B₂O₃ and 10 wt % or less ZnO.

22. The method as set forth in claim 15, wherein the primarily heat treating is performed at 600-800° C.

23. The method as set forth in claim 15, wherein the secondarily heat treating is performed at 600-800° C.

24. A method of manufacturing a semiconductive chip device having an insulating coating layer, comprising:
preparing a semiconductive ceramic laminate, which includes dielectric layers and inner electrodes alternately interposed between the dielectric layers, and etching the semiconductive ceramic laminate;
dipping the etched ceramic laminate into a silane coupling solution, and drying the ceramic laminate;
attaching glass powder to the surface of the dried ceramic laminate, and primarily heat treating the ceramic laminate; and
forming outer electrodes on the primarily heat treated ceramic laminate, secondarily heat treating the ceramic laminate, and plating the outer electrodes.

25. The method as set forth in claim 24, wherein the etching of the semiconductive ceramic laminate is performed using a 0.1-10% HCl solution.

26. The method as set forth in claim 24, wherein the silane coupling solution includes a 0.5-20% silane coupling agent.

27. The method as set forth in claim 26, wherein the silane coupling agent comprises any one selected from among 2-(3,4-epoxycyclohexyl)ethyltrimethoxysilane, 3-glycidoxypropyl trimethoxysilane, 3-glycidoxypropyl methyldiethoxy silane, and 3-glycidoxypropyl triethoxysilane.

28. The method as set forth in claim 24, wherein the glass powder is selected from among Bi₂O₃, B₂O₃, Al₂O₃, P₂O₅, SnO₂, SiO₂, ZnO, Li₂O₃, K₂O, and mixtures thereof.

29. The method as set forth in claim 24 or 28, wherein the glass powder is P₂O₅—ZnO—Al₂O₃ based powder comprising 30-60 wt % P₂O₅, 30-60 wt % ZnO and 10 wt % or less Al₂O₃.

30. The method as set forth in claim 24 or 28, wherein the glass powder is SiO₂—Bi₂O₃—B₂O₃—ZnO based powder comprising 10 wt % or less SiO₂, 20-90 wt % Bi₂O₃, 10-40 wt % B₂O₃ and 10 wt % or less ZnO.

31. The method as set forth in claim 24, wherein the primarily heat treating is performed at 600-800° C.

32. The method as set forth in claim 24, wherein the secondarily heat treating is performed at 600-800° C.

33. The method as set forth in claim 24, wherein the dielectric layer includes any one selected from among ZnO, BiO₂, MnO₂, Sb₂O₅, Co₂O₃, and mixtures thereof.

34. The method as set forth in claim 24, wherein the drying is performed in a range of from room temperature to 150° C.

35. A semiconductive chip device, manufactured according to the method of claim 15 or 24.
